(19) United States
(12) Patent Application Publication
(10) Pub. No.: US 2026/0114238 A1
(43) Pub. Date: Apr. 23, 2026

(54) HEATER HEAD AND SEMICONDUCTOR BONDING APPARATUS INCLUDING THE SAME

(71) Applicant: Samsung Electronics Co., Ltd., Suwon-si (KR)

(72) Inventors: Sangsun Lee, Suwon-si (KR); Jeongdeok Choi, Anseong-si (KR); Junsik Han, Anseong-si (KR); Youngchul Park, Suwon-si (KR); Changil Yi, Suwon-si (KR)

(73) Assignees: Samsung Electronics Co., Ltd., Suwon-si (KR); MiCo Ltd., Anseong-si (KR)

(21) Appl. No.: 19/098,459

(22) Filed: Apr. 2, 2025

(30) Foreign Application Priority Data
Oct. 22, 2024 (KR) 10-2024-0144878

(51) Int. Cl. H01L 21/683; H01L 23/00

(52) U.S. Cl. CPC H10P 72/78; H10W 72/07141

(57) ABSTRACT

A heater head may include a heater head unit having a vacuum conduit hole formed in an external surface thereof; a heater insulation block disposed in a lower portion of the heater head unit; a heater base unit disposed in a lower portion of the heater insulation block; a first vacuum conduit communicating from the vacuum conduit hole of the heater head unit to the heater insulation block and the heater base unit in an arrangement direction of the heater head unit, the heater insulation block and the heater base unit; a second vacuum conduit extending into the heater base unit in a portion of an outer side of the heater base unit and communicating with the first vacuum conduit; and a conduit bushing inserted into at least one of the first vacuum conduit and the second vacuum conduit and forming a vacuum conduit.

### CROSS-REFERENCE TO RELATED APPLICATIONS

This application claims benefit of priority to Korean Patent Application No. 10-2024-0144878 filed on Oct. 22, 2024 in the Korean Intellectual Property Office, the disclosure of which is incorporated herein by reference in its entirety.

### BACKGROUND

Example embodiments of the present disclosure relate to a heater head used to bond a die, a semiconductor chip, or the like, to a printed circuit board and a bonding apparatus including the same.

A semiconductor bonding apparatus for bonding a semiconductor die may bond a die, a semiconductor chip, an interposer, a semiconductor package, or the like, to another semiconductor chip, a semiconductor package, a printed circuit board, or the like, by thermal compression of a heater head of a bonding apparatus.

### SUMMARY

Example embodiments of the present disclosure are to provide a heater head in which a vacuum conduit having internal blockage may be cleaned by replacing components rather than cleaning.

Example embodiments of the present disclosure are to provide a semiconductor bonding apparatus in which a vacuum conduit of a heater head having internal blockage may be cleaned without removing the heater head from a facility.

According to some embodiments of the present disclosure, a heater head includes a heater head unit having a vacuum conduit hole formed in an external surface thereof; a heater insulation block disposed in a lower portion of the heater head unit; a heater base unit disposed in a lower portion of the heater insulation block; a first vacuum conduit communicating from the vacuum conduit hole of the heater head unit to the heater insulation block and the heater base unit in an arrangement direction of the heater head unit, the heater insulation block and the heater base unit; a second vacuum conduit extending into the heater base unit in a portion of an outer side of the heater base unit and communicating with the first vacuum conduit; and a conduit bushing inserted into at least one of the first vacuum conduit and the second vacuum conduit and forming a vacuum conduit.

According to some embodiments of the present disclosure, a heater head of a semiconductor bonding apparatus includes a heater head unit stacked in a direction opposing a bonding component, having a vacuum conduit hole formed in an external surface, and having an increasing surface temperature; a heater insulation block disposed in a lower portion of the heater head unit and preventing transfer of heat; a heater base unit disposed in a lower portion of the heater insulation block and controlling a temperature of the heater head unit; a first vacuum conduit communicating from the vacuum conduit hole of the heater head unit to the heater insulation block and the heater base unit in an arrangement direction of the heater head unit, the heater insulation block and the heater base unit; a second vacuum conduit extending into the heater base unit in a portion of an outer side of the heater base unit and communicating with the first vacuum conduit; and a first conduit bushing inserted into the first vacuum conduit and forming the first vacuum conduit.

According to some embodiments of the present disclosure, a semiconductor bonding apparatus including a vacuum formation unit suctioning air to create a vacuum, a refrigerant supply unit supplying refrigerant, a heater head vacuum-suctioning and heating a bonding component, and a moving main body unit adjusting a position of the heater head is provided, wherein the heater head includes a heater head unit having a vacuum conduit hole formed in an external surface thereof and having an increasing surface temperature; a heater insulation block disposed in a lower portion of the heater head unit and preventing transfer of heat; a heater base unit disposed in a lower portion of the heater insulation block and adjusting a temperature of the heater head unit; a first vacuum conduit communicating from the vacuum conduit hole of the heater head unit to the heater insulation block and the heater base unit in an arrangement direction of the heater head unit, the heater insulation block and the heater base unit; a second vacuum conduit extending into the heater base unit in a portion of an outer side of the heater base unit and communicating with the first vacuum conduit; a first conduit bushing inserted into the first vacuum conduit and forming a vacuum conduit; a second conduit bushing inserted into the second vacuum conduit and forming a vacuum conduit; and a refrigerant conduit forming a conduit separate from the second vacuum conduit in the heater base unit, wherein the first conduit bushing is inserted into a communication hole formed in the second conduit bushing and a vacuum conduit is formed.

According to some embodiments, there is provided a manufacturing method which may include: adjusting a position of a heater head using a moving main body unit; disposing a first bonding component on a second bonding component; and using the heater head, performing vacuum-suctioning and heating of the first bonding component and second bonding component.

In some such embodiments, the method may further include using a vacuum formation unit to suction air to create a vacuum.

In some such embodiments, the heater head may include: a heater head unit having a vacuum conduit hole formed in an external surface thereof; a heater insulation block disposed on the heater head unit and preventing transfer of heat; a heater base unit disposed on the heater insulation block and adjusting a temperature of the heater head unit; a first vacuum conduit defined at least in part by the vacuum conduit hole of the heater head unit, the heater insulation block, and the heater base unit; a second vacuum conduit extending into the heater base unit through an external surface of the heater base unit and communicating with the first vacuum conduit; a first conduit bushing inserted into the first vacuum conduit and forming a vacuum conduit; a second conduit bushing inserted into the second vacuum conduit and forming a vacuum conduit; and a refrigerant conduit forming a conduit separate from the second vacuum conduit in the heater base unit, wherein the first conduit bushing is inserted into a communication hole formed in the second conduit bushing and a vacuum conduit is formed.

In some such embodiments, the method may include using said heater head to perform one or more steps thereof.

In some embodiments, the method may include using a refrigerant supply unit to supply refrigerant.

In some embodiments, the first conduit bushing may be formed of a material having a same level of thermal conductivity as a thermal conductivity of a material of the heater head unit, and the material of the heater head unit and the first conduit bushing may be at least one of AlN, Al2O3 or SiC.

### BRIEF DESCRIPTION OF THE DRAWINGS

The above and other aspects, features, and advantages of the present disclosure will be more clearly understood from the following detailed description, taken in combination with the accompanying drawings, in which:

FIG. 1 is a diagram illustrating a semiconductor bonding apparatus according to some embodiments of the present disclosure;

FIG. 2 is a perspective diagram illustrating a first example embodiment of a heater head of a semiconductor bonding apparatus according to some embodiments of the present disclosure;

FIG. 3 is a perspective diagram illustrating a second example embodiment of a heater head of a semiconductor bonding apparatus according to some embodiments of the present disclosure;

FIG. 4 is a perspective diagram illustrating a heater head of a semiconductor bonding apparatus in FIG. 3;

FIG. 5 is a cross-sectional diagram illustrating a first example embodiment taken along line A-A′ in FIG. 3;

FIG. 6 is a cross-sectional diagram illustrating a second example embodiment taken along line A-A′ in FIG. 3;

FIG. 7 is an enlarged cross-sectional diagram illustrating portion C in FIG. 5;

FIG. 8 is an enlarged cross-sectional diagram illustrating a first example embodiment of portion D in FIG. 6;

FIG. 9 is an enlarged cross-sectional diagram illustrating a second example embodiment of portion D in FIG. 6;

FIG. 10 is an enlarged cross-sectional diagram illustrating a first example embodiment of portion E in FIG. 6;

FIG. 11 is an enlarged cross-sectional diagram illustrating a second example embodiment of portion E in FIG. 6; and

FIG. 12 is a cross-sectional diagram taken along line B-B′ in FIG. 3.

### DETAILED DESCRIPTION

Hereinafter, embodiments of the present disclosure will be described with reference to the accompanying drawings.

A semiconductor bonding apparatus may bond a die, a semiconductor chip, or the like, to be bonded to a printed circuit board by vacuum-suction and applying heat.

Accordingly, the heater head of the semiconductor bonding apparatus may include a vacuum conduit for creating a vacuum and a heater for thermal compression.

In the thermal compression bonding process by the semiconductor bonding apparatus, a sufficiently high level of heat flux may be formed, such that flux fumes, a source of contamination, may frequently occur, which may cause internal blockage of the vacuum conduit.

The vacuum conduit may be formed with a relatively small diameter, such that it may be difficult to clean the vacuum conduit. The heater head may need to be separated to be cleaned, which may lower facility operation efficiency.

The inventors have appreciated that a conduit bushing can be inserted into a vacuum conduit to form a vacuum conduit therein. In some embodiments, the conduit bushing may include a tube that allows for vacuum pressure to be formed therethrough. The conduit bushing may be removable and replaceable. In some embodiments, the conduit bushing may be stably supported without rotation or separation (during operation). The conduit bushing may be susceptible to flux fumes as with other vacuum conduits. The removeable conduit bushing forming the vacuum conduit can be replaced when blocked by flux fume generated during the semiconductor chip bonding process mentioned herein. This replacement process (e.g., instead of cleaning a vacuum conduit) can reduce time required to clean a vacuum conduit, thereby increasing efficiency.

### Semiconductor Bonding Apparatus

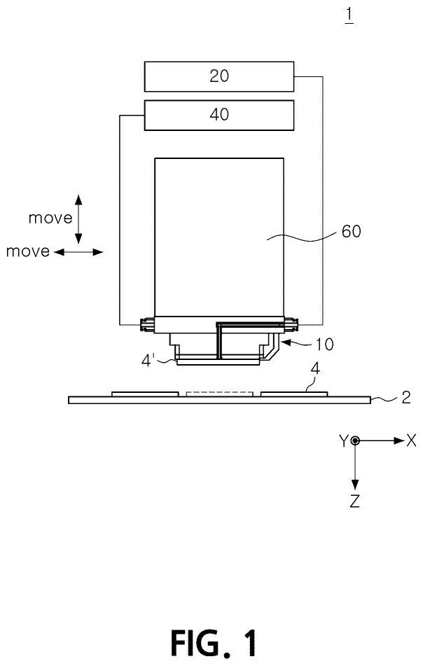

FIG. 1 is a diagram illustrating a semiconductor bonding apparatus according to some embodiments.

A semiconductor bonding apparatus 1 according to some embodiments may include a heater head 10, a vacuum formation unit 20, a refrigerant supply unit 40, and a moving main body unit 60.

The heater head 10 may be mounted on the moving main body unit 60 and may move horizontally and vertically by driving of the moving main body unit 60. The heater head 10 may pick up individualized bonding components 4 and 4′ through a sawing process, may dispose the portions on a printed circuit board 2 or the other semiconductor bonding component and may bond the portions.

The bonding components 4 and 4′ may include a semiconductor die, a semiconductor chip, an interposer, and a semiconductor package. The bonding components 4 and 4′ may be bonded to the printed circuit board 2 or the other semiconductor chip or a semiconductor package through thermal compression of the heater head 10.

The heater head 10 may be connected to the vacuum formation unit 20 and the refrigerant supply unit 40. The vacuum formation unit 20 may include a vacuum pump and a valve for suctioning air when suctioning the bonding component 4′ to the heater head 10.

The refrigerant supply unit 40 may include a refrigerant source and a valve, and may cool the heater head 10 having a high temperature.

In the description below, the heater head 10 will be described in greater detail.

First, for ease of description of the heater head 10 in the example embodiment, the directions may be defined.

In FIG. 1, the direction in which the heater head 10 is directed to the bonding component 4′ may be defined as the upward direction (e.g., the Z-direction in the drawing, hereinafter referred to as “Z” direction), and the direction in which the heater head 10 moves perpendicular to the upward direction Z may be defined as the horizontal direction (e.g., X-direction or the Y-direction in the drawing, hereinafter referred to as “X” or “Y”).

These directions are defined for ease of description, and the upward direction and the downward direction may be arbitrarily selected.

### Heater Head

The heater head 10 according to some embodiments may be mounted on a moving main body unit 60, may move horizontally and vertically by driving of the moving main body unit 60, may pick up bonding components 4 and 4′ by vacuum, may dispose the portions on the printed circuit board 2 or the other semiconductor bonding component, and may bond the portions by thermal compression.

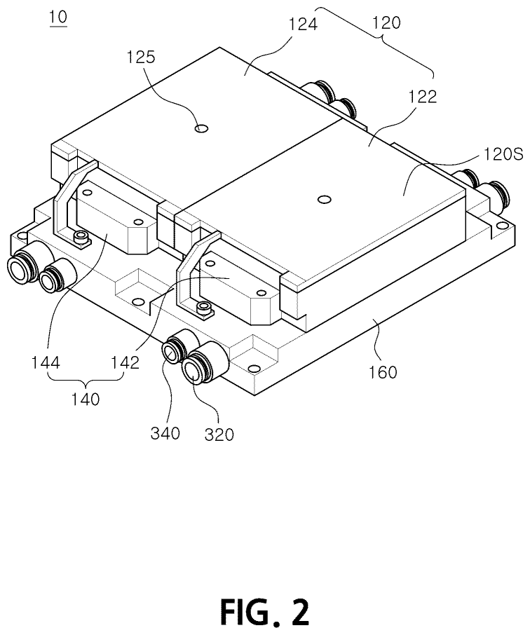

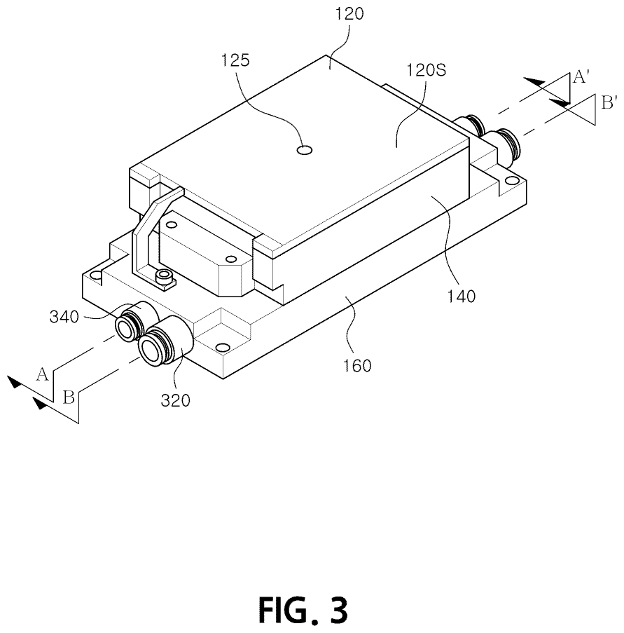

FIG. 2 is a perspective diagram illustrating a first example embodiment of a heater head of a semiconductor bonding apparatus according to some embodiments. FIG. 3 is a perspective diagram illustrating a second example embodiment of a heater head of a semiconductor bonding apparatus according to some embodiments.

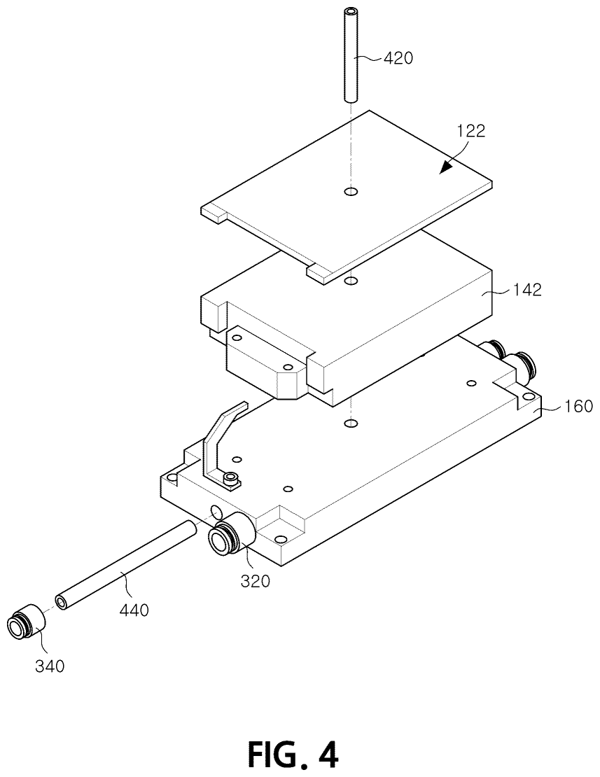

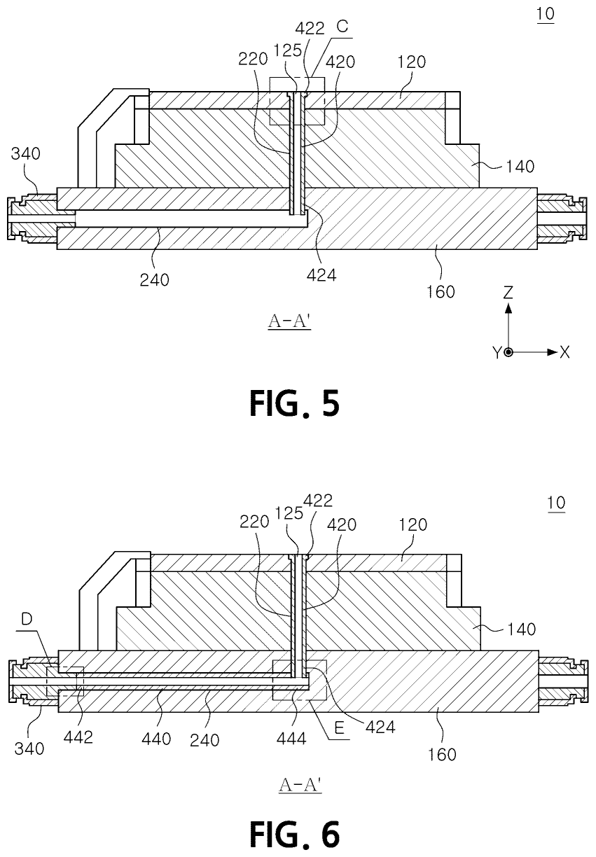

FIG. 4 is a perspective diagram illustrating a heater head of a semiconductor bonding apparatus in FIG. 3. FIG. 5 is a cross-sectional diagram illustrating a first example embodiment taken along line A-A′ in FIG. 3. FIG. 6 is a cross-sectional diagram illustrating a second example embodiment taken along line A-A′ in FIG. 3.

Referring to FIGS. 2 to 6, the heater head 10 according to some embodiments may include a heater head unit 120, a heater insulation block 140, and a heater base unit 160.

The heater head unit 120 may be manufactured using a ceramic material including a heating wire for heating and may have a rectangular plate shape. A vacuum conduit hole 125 for suctioning the bonding components 4 and 4′ may be included on an external surface 120S of the heater head unit 120.

The heater insulation block 140 may be disposed on (directly or with an intervening element therebetween) or in a lower portion of the heater head unit 120 and may block heat conduction of the heater head unit 120 having a high temperature from being transferred to the heater base unit 160 disposed in a lower portion of the heater insulation block 140 (e.g., may prevent transfer of heat at least in part). The heater insulation block may be disposed to prevent transfer of heat between the heater head unit and the heater base unit. As shown, the heater insulation block is positioned between the heater head unit and heater base unit.

The heater insulation block 140 may have a rectangular shape in accordance with the size and the shape of the heater head unit 120, but the disclosure is not limited thereto. Also, a thickness of the heater insulation block 140 may be appropriately selected in consideration of the temperature rise range of the heater head unit 120.

The heater base unit 160 may be disposed on (directly or with an intervening element therebetween) or in a lower portion of the heater insulation block 140 and may adjust the temperature of the heater head unit 120.

Referring to FIGS. 2 and 3, in the heater head 10, two heater head units 120 and two heater insulation blocks 140 may be provided and connected, depending on the size of bonding components 4 and 4′.

However, the disclosure is not limited thereto, and the size of one heater head unit 120 may also be configured as the combined size of the first heater head unit 122 and the second heater head unit 124 as in FIG. 2.

When two heater head units 120 are provided as in FIG. 2, the first heater insulation block 142 and the second heater insulation block 144 may also be provided in lower portions of the first heater head unit 122 and the second heater head unit 124, respectively, in a corresponding manner.

Also, if desired, one or two heater base units 160 controlling the temperature of the heater head unit 120 may be disposed.

Referring to FIG. 5, a vacuum conduit of the heater head 10 according to some embodiments may be formed.

The first vacuum conduit 220 may be communicated from the vacuum conduit hole 125 of the heater head unit 120 to the heater insulation block 140 and the heater base unit 160 in an arrangement direction of the heater head unit 120, the heater insulation block 140 and the heater base unit 160. The first vacuum conduit 220 may be defined at least in part by the vacuum conduit hole 125 of the heater head unit 120, the heater insulation block 140, and the heater base unit 160.

The second vacuum conduit 240 may extend into the heater base unit 160 in a portion of the outer side of the heater base unit 160 (e.g., through an outer side) and may communicate with the first vacuum conduit 220.

In the example embodiment in FIG. 5, a first conduit bushing 420 having a thin tube shape may be inserted and disposed in the first vacuum conduit 220, such that another vacuum conduit may be formed. An internal tube in the first conduit bushing 420 may become another vacuum conduit.

As for the first conduit bushing 420, a bonding agent, screw, snap-in, or the like, may be considered such that the first conduit bushing 420 may be inserted into and fixed to the first vacuum conduit 220 and may not be removed (e.g., during bonding processes).

When the heater head unit 120 and the first vacuum conduit 220 are contaminated by flux fume generated during the bonding process, an operator may remove the contamination by removing the first conduit bushing 420 from the first vacuum conduit 220 in the upward direction Z, cleaning the conduit, and reattaching or replacing the conduit without disassembling the heater head 10.

In the example embodiment in FIG. 6, a second conduit bushing 440 may be inserted and disposed in the second vacuum conduit 240 extending into the heater base unit 120 in a portion of the outer side of the heater base unit 160, such that another vacuum conduit may be formed.

Also as for the second conduit bushing 440, a bonding agent, screw, snap-in, or the like, may be considered such that the second conduit bushing 440 may be inserted into and fixed to the first vacuum conduit 220 and may not be removed (e.g., during bonding processes).

When the flux fume generated during the bonding process contaminates both the first conduit bushing 420 and the second vacuum conduit bushing 440 of the heater head unit 120, an operator may remove the contamination by removing the first conduit bushing 420 from the first vacuum conduit 220 and the second conduit bushing 440 from second vacuum conduit 240 in the upward direction Z or in the X direction, cleaning the components, and reattaching or replacing the components without disassembling the heater head 10.

When the vacuum formation unit 20 in FIG. 1 is driven and suctions air, vacuum pressure may be formed through the second conduit bushing 440 and the vacuum conduit of the first conduit bushing 420 communicating with the second conduit bushing 440, such that the bonding component in contact with the heater head unit 120 may be suctioned.

In the description below, the coupling between the first conduit bushing 420 and the second conduit bushing 440 will be described in greater detail.

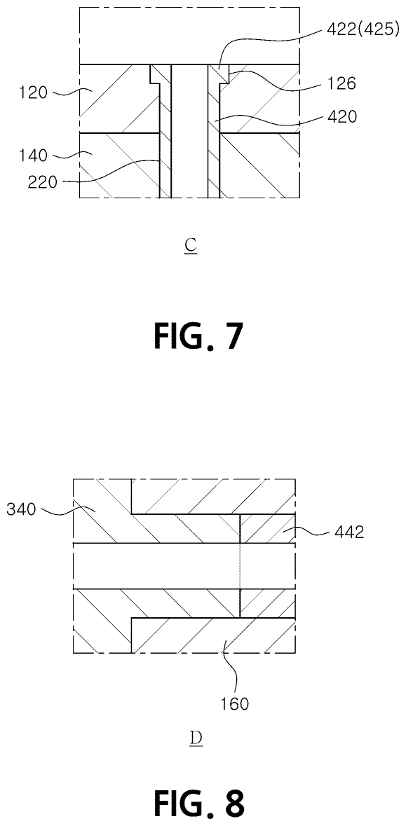

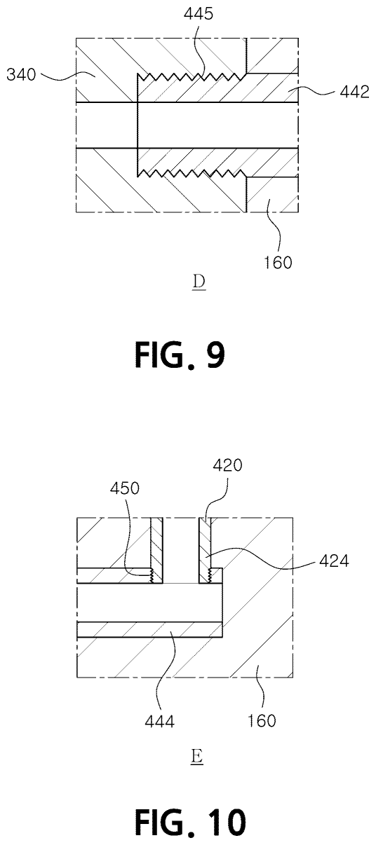

FIG. 7 is an enlarged cross-sectional diagram illustrating portion C in FIG. 5. FIG. 8 is an enlarged cross-sectional diagram illustrating a first example embodiment of portion D in FIG. 6. FIG. 9 is an enlarged cross-sectional diagram illustrating a second example embodiment of portion D in FIG. 6.

Referring to FIG. 7, the first conduit bushing 420 inserted into the first vacuum conduit 220 may include a first end 422 in contact with an external surface of the heater head unit 120 so as to be coplanar with the external surface. As illustrated in FIG. 5, the second end 424 of the first conduit bushing 420 may extend to the second vacuum conduit 240.

In order to increase a bonding area of the first conduit bushing 420 inserted into the first vacuum conduit 220, the first end 422 of the first conduit bushing 420 may include a flange portion 425, and the heater head unit 120 may include a recess 126 corresponding to the flange portion 425.

Also, referring to FIG. 5 and FIG. 8, the second conduit bushing 440 inserted into the second vacuum conduit 240 may include a first end 442 directed to a portion of the outer side of the heater base unit 160 and a second end 444 directed to the first vacuum conduit 220.

The vacuum formation unit 20 and the second vacuum conduit 240 may communicate with each other, and a first fitting tube 340 may be further provided to connect a tube of the vacuum formation unit 20 to the second vacuum conduit 240.

The first fitting tube 340 may be inserted into the second vacuum conduit 240 in a portion of the outer side of the heater base unit 160 and may communicate with the first end 442 of the second conduit bushing 440.

In this case, as illustrated in FIG. 8, the first fitting tube 340 may be inserted into the second conduit bushing 440 by being snapped-in with the same diameter as that of the second conduit bushing 440.

Also, as illustrated in FIG. 9, the first fitting tube 340 may be screw-coupled 445 with the first end 442 of the second conduit bushing 440, exposed to a portion of the outer side of the heater base unit 160. Specifically, screw threads may be formed on the external surface of the first end 442 of the second conduit bushing 440, exposed to a portion of the outer side of the heater base unit 160, and screw threads corresponding to the internal surface of the first fitting tube 340 may be formed and coupling may be performed.

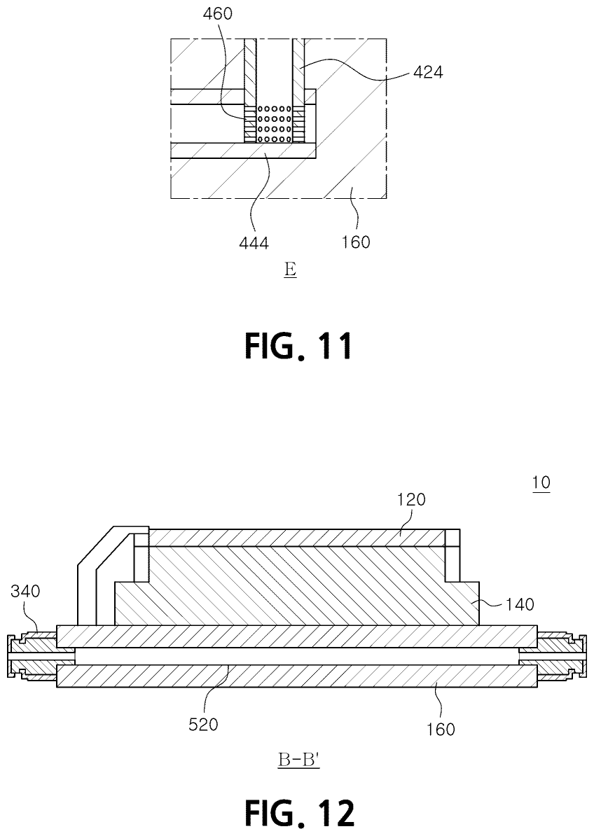

FIG. 10 is an enlarged cross-sectional diagram illustrating a first example embodiment of portion E in FIG. 6. FIG. 11 is an enlarged cross-sectional diagram illustrating a second example embodiment of portion E in FIG. 6.

A state of connection between the first conduit bushing 420 and the second conduit bushing 440 may be described with reference to FIGS. 10 and 11.

Referring to the example embodiment in FIG. 10, the second end 424 of the first conduit bushing 420 may extend to a communication hole of the second end 444 of the second conduit bushing 440, and may be screw-coupled 450 with the communication hole of the second conduit bushing 440.

In this way, when the second end 424 of the first conduit bushing 420 and the second end 444 of the second conduit bushing 440 are screw-coupled to each other, the spinning or rotating of the first conduit bushing 420 in the first vacuum conduit 220 may be eliminated, and the spinning or rotating of the second conduit bushing 440 in the second vacuum conduit 240 may be eliminated.

Referring to FIG. 11, the second end 424 of the first conduit bushing 420 may extend to a lower side of the communication hole of the second conduit bushing 440, and the second end 424 of the first conduit bushing 420 extending to the lower side of the communication hole may include an airflow porous hole 460.

When the second end 424 of the first conduit bushing 420 extends to the internal side of the second conduit bushing 440 as described above, the contact area between the first conduit bushing 420 and the second conduit bushing 440 may increase, such that the first conduit bushing 420 and the second conduit bushing 440 may be stably mutually supported.

As the conduit bushing 420 and 440, a material having the same level of thermal conductivity as that of a material of the heater head unit 120 may be selected.

For example, the material of the heater head unit 120 and the conduit bushings 420 and 440 may be at least one of AlN, Al₂O₃ or SiC.

When the heater head unit 120 and the conduit bushing 420 and 440, especially the first conduit bushing 420, are formed of the same material or similar materials, the heating or cooling temperature may be changed with high uniformity throughout the heater head unit 120.

Also, in order to maintain high uniformity (e.g., uniformity in 10%) throughout the heater head unit 120 in terms of temperature changes of heating or cooling, the area of the first conduit bushing 420 may be maintained in 5% of the area of the heater head unit 120.

FIG. 12 is a cross-sectional diagram taken along line B-B′ in FIG. 3.

Referring to FIG. 12, when the heater head unit 120 is raised to a high temperature, a refrigerant conduit 520 in which refrigerant is supplied from the refrigerant supply unit 40 and flows in order to lower the temperature may be included.

The refrigerant supply unit 40 and the refrigerant conduit 520 illustrated in FIG. 1 may communicate with each other, and a second fitting tube 320 may be further provided to connect the tube through which the refrigerant of the refrigerant supply unit 40 Flows to the Refrigerant Conduit 520.

The second fitting tube 320 may communicate with another refrigerant conduit 520, separate from the second vacuum conduit 240 of the heater base unit 160.

The second fitting tube 320 may be inserted into and connected to the refrigerant conduit 520 in a portion of the outer side of the heater base unit 160. As illustrated in FIG. 12, the second fitting tube 320 may be inserted into the refrigerant conduit 520 by being snapped-in with substantially the same diameter as that of the refrigerant conduit 520.

The refrigerant conduit 520 may be formed in the horizontal direction X of the heater base unit 160 in some embodiments, or may also be formed in the entire heater base unit 160 in the vertical direction relative to the horizontal direction X.

When the refrigerant supply unit 40 is driven and refrigerant flows through the refrigerant conduit 520 of the heater base unit 160, the temperature of the heater head unit 120 may be lowered. The heater insulation block 140 may alleviate rapid temperature changes.

According to some embodiments, there is provided a method of manufacturing a semiconductor component as described herein. The method may include using one or more elements described herein.

The manufacturing method may include: adjusting a position of a heater head using a moving main body unit; disposing a first bonding component on a second bonding component; and using the heater head, performing vacuum-suctioning and heating of the first bonding component and second bonding component.

In some such embodiments, the method may further include using a vacuum formation unit to suction air to create a vacuum.

In some such embodiments, the heater head may include: a heater head unit having a vacuum conduit hole formed in an external surface thereof; a heater insulation block disposed on the heater head unit and preventing transfer of heat; a heater base unit disposed on the heater insulation block and adjusting a temperature of the heater head unit; a first vacuum conduit defined at least in part by the vacuum conduit hole of the heater head unit, the heater insulation block, and the heater base unit; a second vacuum conduit extending into the heater base unit through an external surface of the heater base unit and communicating with the first vacuum conduit; a first conduit bushing inserted into the first vacuum conduit and forming a vacuum conduit; a second conduit bushing inserted into the second vacuum conduit and forming a vacuum conduit; and a refrigerant conduit forming a conduit separate from the second vacuum conduit in the heater base unit, wherein the first conduit bushing is inserted into a communication hole formed in the second conduit bushing and a vacuum conduit is formed.

In some such embodiments, the method may include using said heater head to perform one or more steps thereof.

In some embodiments, the method may include using a refrigerant supply unit to supply refrigerant.

In some embodiments, the first conduit bushing may be formed of a material having a same level of thermal conductivity as a thermal conductivity of a material of the heater head unit, and the material of the heater head unit and the first conduit bushing may be at least one of AlN, Al₂O₃ or SiC.

According to the aforementioned example embodiments, by replacing the bushing forming the vacuum conduit blocked by flux fume generated during the semiconductor chip bonding process, rather than cleaning the vacuum conduit, cleaning time may be reduced.

Also, the bushing in the vacuum conduit may be firmly fixed, and the heater head may be maintained and replaced without being separated from the semiconductor bonding apparatus, thereby improving the facility operation efficiency of the semiconductor bonding apparatus.

While the example embodiments have been illustrated and described above, it will be configured as apparent to those skilled in the art that modifications and variations could be made without departing from the scope of the present disclosure as defined by the appended claims.

What is claimed is:

1. A heater head, comprising:
a heater head unit having a vacuum conduit hole formed in an external surface thereof;
a heater base unit;
a heater insulation block disposed to prevent transfer of heat between the heater head unit and the heater base unit;
a first vacuum conduit defined at least in part by the vacuum conduit hole of the heater head unit, the heater insulation block, and the heater base unit;
a second vacuum conduit extending into the heater base unit through an outer side of the heater base unit and communicating with the first vacuum conduit; and
a conduit bushing inserted into at least one of the first vacuum conduit and the second vacuum conduit and forming a vacuum conduit.

2. The heater head of claim 1,
wherein the conduit bushing includes a first conduit bushing inserted into the first vacuum conduit,
wherein the first conduit bushing includes:
a first end in contact with the external surface of the heater head unit; and
a second end extending to the second vacuum conduit.

3. The heater head of claim 2,
wherein an upper portion of the first end includes a flange portion, and
wherein the heater head unit has a recess corresponding to the flange portion.

4. The heater head of claim 2,
wherein the conduit bushing includes a second conduit bushing inserted into the second vacuum conduit,
wherein the second conduit bushing includes:
a first end directed toward a portion of the outer side of the heater base unit; and
a second end directed toward the first vacuum conduit, and
wherein a communication hole is formed in one side of the second end into which a second end of the first conduit bushing is inserted.

5. The heater head of claim 4, wherein the second end of the first conduit bushing extends to the communication hole of the second conduit bushing and is screw-coupled with the communication hole of the second conduit bushing.

6. The heater head of claim 4,
wherein the second end of the first conduit bushing extends to a lower side of the communication hole of the second conduit bushing, and
wherein the second end of the first conduit bushing extending to a lower side of the communication hole includes an airflow porous hole.

7. The heater head of claim further comprising:
a first fitting tube inserted into the second vacuum conduit in a portion of the outer side of the heater base unit and communicating with the first end of the second conduit bushing.

8. The heater head of claim 4, further comprising:
a first fitting tube screw-coupled with the first end of the second conduit bushing, exposed to a portion of the outer side of the heater base unit.

9. The heater head of claim 4,
wherein the conduit bushing is formed of a material having a same level of thermal conductivity as a thermal conductivity of a material of the heater head unit, and
wherein the material of the heater head unit and the conduit bushing is at least one of AlN, Al₂O₃ or SiC.

10. The heater head of claim 1, further comprising:
a refrigerant conduit forming a conduit separate from the second vacuum conduit of the heater base unit; and
a second fitting tube inserted into a hole of the refrigerant conduit formed in a portion of the outer side of the heater base unit.

11. A heater head of a semiconductor bonding apparatus, the heater head comprising:
a heater head unit having a vacuum conduit hole formed in an external surface;
a heater base unit configured to control a temperature of the heater head unit;
a heater insulation block disposed to prevent transfer of heat between the heater head unit and the heater base unit;
a first vacuum conduit defined at least in part by the vacuum conduit hole of the heater head unit, the heater insulation block, and the heater base unit;
a second vacuum conduit extending into the heater base unit through an outer side of the heater base unit and communicating with the first vacuum conduit; and
a first conduit bushing inserted into the first vacuum conduit and forming the first vacuum conduit.

12. The heater head of claim 11,
wherein the first conduit bushing includes:
a first end in contact with the external surface of the heater head unit so as to be coplanar with the external surface; and
a second end extending to the second vacuum conduit,
wherein an upper portion of the first end includes a flange portion, and
wherein the heater head unit has a recess corresponding to the flange portion.

13. The heater head of claim 12, further comprising:
a second conduit bushing inserted into the second vacuum conduit,
wherein the second conduit bushing includes:
a first end directed to a portion of the outer side of the heater base unit; and
a second end directed to the first vacuum conduit,
wherein a communication hole into which the second end of the first conduit bushing is inserted is formed in one side of the second end.

14. The heater head of claim 13, wherein the second end of the first conduit bushing extends to the communication hole of the second conduit bushing and is screw-coupled with the communication hole of the second conduit bushing.

15. The heater head of claim 13,
wherein the second end of the first conduit bushing extends to a lower side of the communication hole of the second conduit bushing, and
wherein the second end of the first conduit bushing extending to a lower side of the communication hole includes an airflow porous hole.

16. The heater head of claim 13, further comprising:
a first fitting tube inserted into the second vacuum conduit in a portion of the outer side of the heater base unit and communicating with the first end of the second conduit bushing.

17. The heater head of claim 13, further comprising:
a first fitting tube screw-coupled with the first end of the second conduit bushing, exposed to a portion of the outer side of the heater base unit.

18. The heater head of claim 13,
wherein the first conduit bushing is formed of a material having a same level of thermal conductivity as a thermal conductivity of a material of the heater head unit, and
the material of the heater head unit and the first conduit bushing is at least one of AlN, Al₂O₃ or SiC.

19. The heater head of claim 11, further comprising:
a refrigerant conduit forming a tube separate from the second vacuum conduit in the heater base unit; and
a second fitting tube inserted into the refrigerant conduit formed in a portion of the outer side of the heater base unit.

20. A semiconductor bonding apparatus including:
a vacuum formation unit configured to suction air to create a vacuum, and
a heater head configured to vacuum-suction and heat a bonding component,
wherein the heater head includes:
a heater head unit having a vacuum conduit hole formed in an external surface thereof;
a heater base unit configured to adjust a temperature of the heater head unit;
a heater insulation block disposed to prevent transfer of heat between the heater head unit and the heater base unit;
a first vacuum conduit defined at least in part by the vacuum conduit hole of the heater head unit, the heater insulation block, and the heater base unit;
a second vacuum conduit extending into the heater base unit through an outer side of the heater base unit and communicating with the first vacuum conduit;
a first conduit bushing inserted into the first vacuum conduit and forming a vacuum conduit;
a second conduit bushing inserted into the second vacuum conduit and forming a vacuum conduit; and
a refrigerant conduit forming a conduit separate from the second vacuum conduit in the heater base unit,
wherein the first conduit bushing is inserted into a communication hole formed in the second conduit bushing and a vacuum conduit is formed.
